(19) United States
(12) Patent Application Publication
(10) Pub. No.: US 2016/0105106 A1
(43) Pub. Date: Apr. 14, 2016

(54) CONTROLLER AND POWER CONVERTER USING THE SAME

(71) Applicant: SAMSUNG ELECTRO-MECHANICS CO., LTD., Suwon-si (KR)

(72) Inventor: Hyun Ku KANG, Seoul (KR)

(73) Assignee: SAMSUNG ELECTRO-MECHANICS CO., LTD., Suwon-si (KR)

(21) Appl. No.: 14/878,648

(22) Filed: Oct. 8, 2015

(30) Foreign Application Priority Data
Oct. 10, 2014 (KR) 10-2014-0136921

(51) Int. Cl. H02M 3/156; H03K 17/284; H03K 17/60; H03K 5/24; H02M 1/08; H03K 17/687

(52) U.S. Cl. CPC H02M 3/156; H02M 1/08; H03K 17/687; H03K 17/60; H03K 5/24; H03K 17/284

(57) ABSTRACT

The object of the present invention is to provide a controller, and a power converter using the same, which can expand the range of a voltage applied to a load.

The present invention provides a controller, which includes a switch signal unit configured to output a control signal repeating a high state and a low state by receiving a first signal and a second signal, a first signal generation unit configured to generate the first signal, and configured to transmit the first signal to the switch signal unit, and a second signal generation unit configured to generate the second signal by comparing a sensing voltage and a variable first reference voltage, and configured to transmit the second signal to the switch signal unit, wherein the first signal generation unit is configured to adjust a transmission time of the first signal by sensing a voltage level of the first reference voltage, and a power converter using the same.

### CROSS-REFERENCE TO RELATED APPLICATIONS

Claim and incorporate by reference domestic priority application and foreign priority application as follows:

### CROSS REFERENCE TO RELATED APPLICATION

This application claims the benefit under 35 U.S.C. Section 119 of Korean Patent Application Serial No. 10-2014-0136921, entitled filed Oct. 10, 2014, which is hereby incorporated by reference in its entirety into this application.

### BACKGROUND OF THE INVENTION

1. Field of the Invention

The present invention relates to a controller and a power converter using the same.

2. Description of the Related Art

In general, switch mode power supplies such as buck converters and flyback converters are used in a wide range of electronic equipment. In particular, when the power supply supplies power to a light emitting diode, the brightness of the light emitting diode can be adjusted by the adjustment of the amount of current flowing through an inductor. When the light emitting diode emits light with low brightness, there is a period in which the current does not flow through the inductor. Thus, it is not easy to control the power supply.

### SUMMARY OF THE INVENTION

The present invention has been invented in order to overcome the above-described problems and it is, therefore, an object of the present invention to provide a controller and a power converter using the same which can expand the range of a voltage applied to a load.

In accordance with a first embodiment of the present invention to achieve the object, there is provided a controller including: a switch signal unit for outputting a control signal repeating a high state and a low state by receiving a first signal and a second signal; a first signal generation unit for generating the first signal and transmitting the first signal to the switch signal unit; and a second signal generation unit for generating the second signal by comparing a sensing voltage and a variable first reference voltage and transmitting the second signal to the switch signal unit, wherein the first signal generation unit adjusts a transmission time of the first signal by sensing a voltage level of the first reference voltage.

In accordance with a second embodiment of the present invention to achieve the object, there is provided a power converter including: an inductor; a switch turned on or turned off according to a control signal to control the flow of a current flowing through the inductor; and a control unit for outputting the control signal, wherein the control unit includes: a switch signal unit for outputting the control signal repeating a high state and a low state by receiving a first signal and a second signal; a first signal generation unit for generating the first signal and transmitting the first signal to the switch signal unit; and a second signal generation unit for generating the second signal by comparing a sensing voltage and a variable first reference voltage and transmitting the second signal to the switch signal unit while adjusting a transmission time of the second signal by varying the first reference voltage, wherein the first signal generation unit adjusts a transmission time of the first signal by sensing a voltage level of the first reference voltage.

In accordance with a third embodiment of the present invention to achieve the object, there is provided a power converter including: a power generation unit for applying a predetermined voltage to a load while making uniform an average of the size of a driving current flowing through an inductor; a sensing unit for sensing the size of the driving current and outputting a sensing voltage corresponding to the size of the driving current; and a control unit for outputting a control signal to make uniform the average of the size of the driving current in response to the size of a first reference voltage while adjusting the average of the size of the driving current by varying a voltage level of the first reference voltage.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a structural diagram showing a power converter in accordance with the present invention;

FIG. 2 is a waveform diagram showing a waveform of a driving current flowing through an inductor of a typical power converter;

FIG. 3 is a circuit diagram showing an embodiment of a power generation unit employed in the power converter shown in FIG. 1;

FIG. 4 is a circuit diagram showing an embodiment of a control unit employed in the power converter shown in FIG. 1; and

FIG. 5 is a waveform diagram showing a waveform of a driving current flowing through an inductor of the power converter shown in FIG. 1.

### DETAILED DESCRIPTION OF THE PREFERABLE EMBODIMENTS

A matter regarding to an operational effect including a technical configuration for an object of a controller and a power converter using the same in accordance with the present invention will be clearly appreciated through the following detailed description with reference to the accompanying drawings showing preferable embodiments of the present invention.

Further, in describing the present invention, descriptions of well-known techniques are omitted so as not to unnecessarily obscure the embodiments of the present invention. In the present specification, the terms “first,” “second,” and the like are used for distinguishing one element from another, and the elements are not limited by the above terms.

In the following detailed description of the present invention, reference is made to the accompanying drawings that show, by way of illustration, specific embodiments in which the present invention may be practiced. These embodiments are described in sufficient detail to enable those skilled in the art to practice the embodiments. It is to be understood that the various embodiments, although different, are not necessarily mutually exclusive. For example, a particular feature, structure, or characteristic described herein, in connection with one embodiment, may be implemented within other embodiments without departing from the spirit and scope of the embodiments. In addition, it is to be understood that the location or arrangement of individual elements within each disclosed embodiment may be modified without departing from the spirit and scope of the embodiments. The following detailed description is, therefore, not to be taken in a limiting sense, and the scope of the embodiments is defined only by the appended claims, appropriately interpreted, along with the full range of equivalents to which the claims are entitled. In the drawings, like numerals refer to the same or similar functionality throughout the several views.

Hereinafter, embodiments of the present invention will be described in detail with reference to the accompanying drawings so that those skilled in the art can easily practice the present invention.

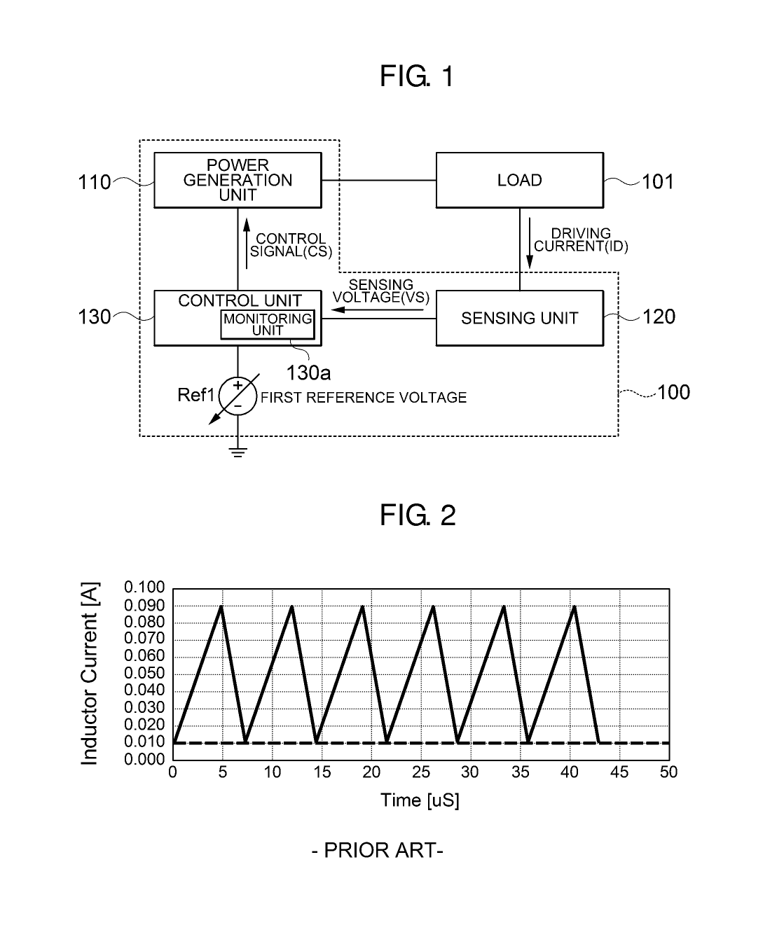

FIG. 1 is a structural diagram showing a power converter in accordance with the present invention.

Referring to FIG. 1, a power converter 100 may include a power generation unit 110 which makes uniform an average of the size of a driving current ID flowing through an inductor L while applying a driving voltage to a load 101, a sensing unit 120 which outputs a sensing voltage in response to the size of a first reference voltage Ref1 and the driving current ID, and a control unit 130 which adjusts the size of the average of the driving current ID by varying a voltage level of the first reference voltage Ref1 while outputting a control signal CS to make uniform the average of the size of the driving current ID in response to the size of the first reference voltage Ref1.

The power generation unit 110 may transmit a predetermined voltage to the load 101 by inducing the predetermined voltage by the driving voltage ID flowing through the inductor L. The sensing unit 120 may sense the size of the driving current ID flowing through the inductor L and transmit the sensing voltage VS corresponding to the size of the sensed driving current ID to the control unit 130. The control unit 130 may receive the sensing voltage VS and control the driving current ID flowing through the inductor L such that the average of the size of the driving current ID flowing through the inductor L becomes a preset amount. The control unit 130 may control the average of the size of the driving current ID flowing through the inductor L to be the preset amount using the first reference voltage Ref1. That is, when the voltage level of the first reference voltage Ref1 is set, the control unit 130 may control the driving current ID having an average current amount corresponding to the set voltage level of the first reference voltage Ref1 to flow through the inductor L. Thus, when the voltage level of the first reference voltage Ref1 is varied, the control unit 130 may vary the amount of the driving current ID flowing through the inductor L in response to a variation in the first reference voltage Ref1. That is, the amount of the current flowing through the load 101 may be adjusted by varying the first reference voltage Ref1. When the amount of the current flowing through the load 101 is adjusted, if the load 101 includes a light emitting diode, brightness of the light emitting diode may be adjusted by varying the first reference voltage Ref1. And, the driving current ID flowing through the inductor L may be increased and reduced by the control of the control unit 130. The control unit 130 may control the average of the driving current ID flowing through the inductor L to be the preset amount having a predetermined size. FIG. 2 is a waveform diagram showing a waveform of a driving current flowing through an inductor in a typical power supply. FIG. 2 shows a state in which an average of the driving current flowing through the inductor is set to 50 mA. The driving current flowing through the inductor L may be increased when a switch SW1 is turned on and reduced when the switch SW1 is turned off. At this time, when the average of the driving current flowing through the inductor L is reduced by varying the first reference voltage Ref1, if the switch SW1 is turned off, a minimum value of the level of the driving current flowing through the inductor L may be reduced to 0 or a value approximate to 0. When the driving current flowing through the inductor L has a value of 0 or a value approximate to 0, there is a problem that the control of the power converter 100 is unstable. In order to overcome this problem, the control unit 130 may further include a monitoring unit 130a for sensing the voltage level of the first reference voltage Ref1 and control the minimum value of the current flowing through the inductor L not to be reduced to less than a predetermined value when the size of the voltage level of the first reference voltage Ref1 sensed by the monitoring unit 130a is below a predetermined level.

When the load 101 receiving power from the power generation unit 110 includes at least one light emitting diode, if the voltage level of the first reference voltage Ref1 is varied, the brightness of the light emitting diode may be adjusted by the control unit 130. Further, when the voltage level of the first reference voltage Ref1 is high, the average of the driving current ID flowing through the inductor L may be large, and when the voltage level of the first reference voltage Ref1 is low, the average of the driving current ID flowing through the inductor L may be small. The monitoring unit 130a may sense the voltage level of the first reference voltage Ref1. When the voltage level of the first reference voltage Ref1 is lower than the predetermined level, the monitoring unit 130a may control the power generation unit 110 such that the size of the driving current ID flowing through the inductor L is not reduced to less than the predetermined value. That is, therefore, when controlling the brightness of the light emitting diode by the flow of the current during dimming control, if the monitoring unit 130a senses that the average of the driving current ID flowing through the inductor L is reduced to less than the set value, the control unit 130 may smoothly control the power converter 100 by not allowing the minimum value of the driving current ID to be 0 or a value approximate to 0.

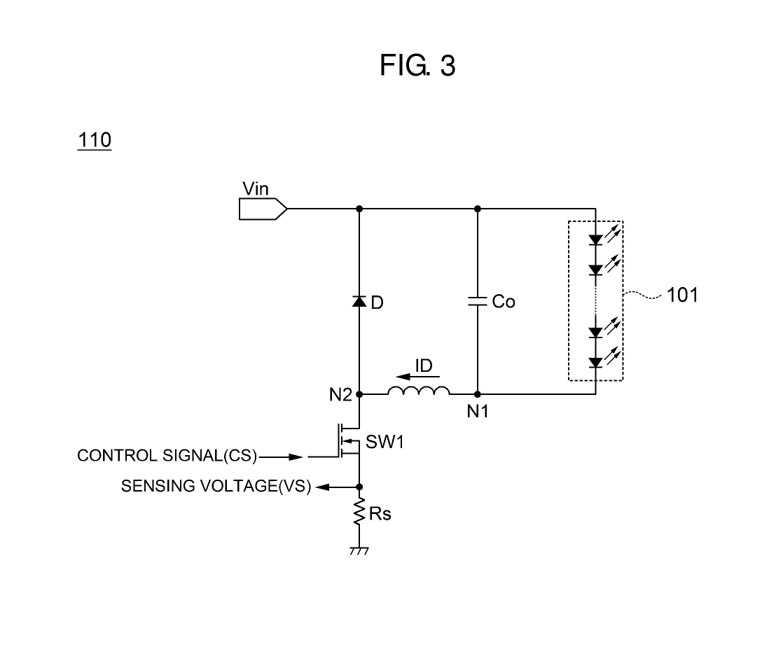

FIG. 3 is a circuit diagram showing an embodiment of the power generation unit employed in the power converter shown in FIG. 1.

Referring to FIG. 3, the power generation unit 110 may include the inductor L and the switch SW1 for adjusting the flow of the driving current ID flowing through the inductor L by receiving the control signal CS repeating a high state and a low state.

In the power generation unit 110, an input voltage may be transmitted through an input terminal Vin, and a first electrode of an output capacitor Co may be connected to the input terminal Vin and a second electrode of the output capacitor Co may be connected to a first node N1. One end of the inductor L may be connected to the first node N1, and the other end of the inductor L may be connected to a second node N2. Further, the load 101 may be connected between the input terminal and the first node N1. Here, although it is shown that the light emitting diodes of the load 101 are connected in series, it is not limited thereto. And, an anode electrode of a diode D may be connected to the input terminal Vin, and a cathode electrode of the diode D may be connected to the second node N2. And, a first electrode of the switch SW1 may be connected to the second node N2, and a second electrode of the switch SW1 may be connected to a ground through the sensing unit 120. Further, a gate electrode of the switch SW1 may be connected to the control unit 130. Here, the power generation unit 110 may be a low side buck converter but is not limited thereto. Further, the sensing unit 120 may include a sensing resistor Rs, and the sensing voltage VS may be a voltage formed by the driving current ID flowing through the sensing resistor Rs. One end of the sensing resistor Rs may be connected to the second electrode of the switch SW1, and the other end of the sensing resistor Rs may be connected to the ground. And, although it is shown that the switch SW1 is a field effect resistor (FET), the switch SW1 is not limited thereto and may be a metal oxide semiconductor (MOS) transistor or a bipolar junction transistor (BJT).

The power generation unit 110 configured as above may control the driving current ID flowing through the inductor L by determining the turn-on/turn-off of the switch SW1 through the control signal CS. At this time, the driving current ID flowing through the inductor L may have the same waveform as the current flowing through the load 101.

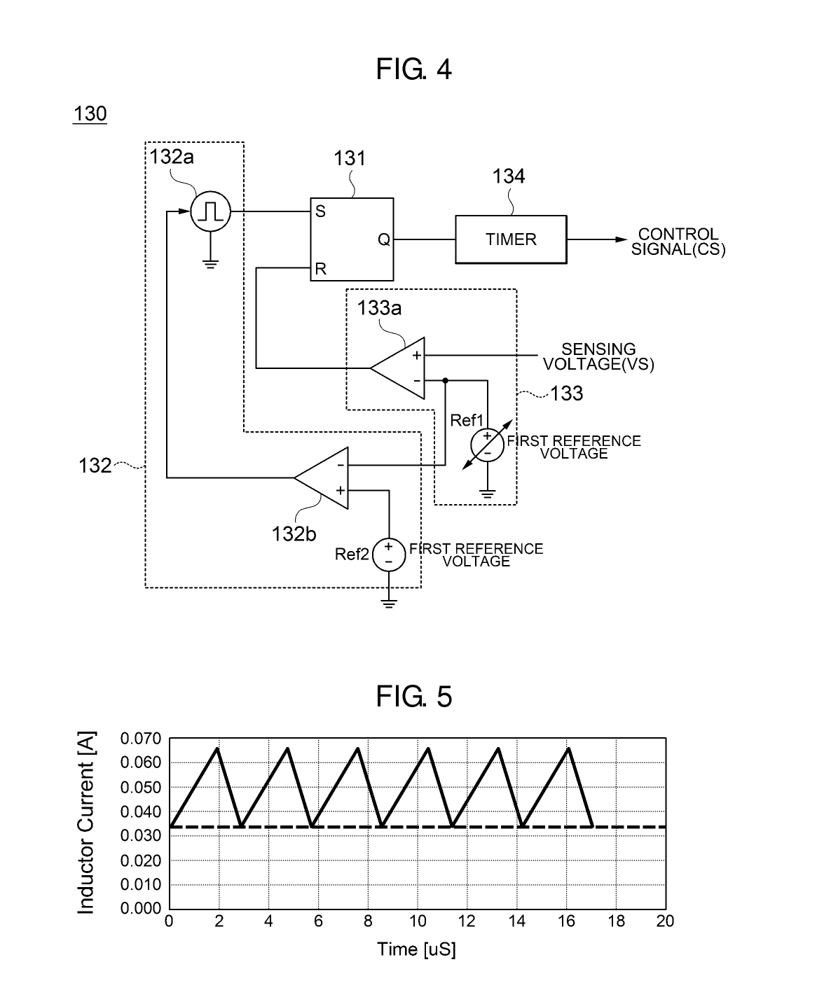

FIG. 4 is a circuit diagram showing an embodiment of the control unit employed in the power converter shown in FIG. 1.

Referring to FIG. 4, the control unit 130 may include a switch signal unit 131 which outputs the control signal CS repeating a high state and a low state by receiving a first signal and a second signal, a first signal generation unit 132 which generates the first signal S to transmit the first signal S to the switch signal unit 131, and a second signal generation unit 133 which generates the second signal R by comparing the sensing voltage VS with the variable first reference voltage Ref1 and transmits the second signal R to the switch signal unit 131.

The switch signal unit 131 may determine the turn-on/turn-off of the switch SW1 by outputting the control signal CS. The switch signal unit 131 may turn on the switch SW1 by the first signal S and turn off the switch SW1 by the second signal R. Here, although it is shown that the switch SW1 is turned on by the control signal CS of a high state and turned off by the control signal CS of a low state, it is not limited thereto. The switch signal unit 131 may be an RS flip-flop but is not limited thereto. Further, the first signal S may be a set signal, and the second signal R may be a reset signal. Further, the switch signal unit 131 may determine a time for turning on the switch SW1 and a time for turning off the switch SW1 by the first signal S and the second signal R.

The first signal generation unit 132 may adjust a transmission time of the first signal S by sensing the voltage level of the first reference voltage Ref1. Further, the first signal generation unit 132 may include an oscillator 132a. The oscillator 132a may adjust the transmission time of the first signal S in response to an output signal of a first comparator 132b. For example, a method for adjusting the transmission time of the first signal S may be a method for adjusting a frequency of the first signal S. Further, the first signal generation unit 132 may further include the first comparator 132b, and the first comparator 132b may compare the first reference voltage Ref1 and a second reference voltage Ref2. The second reference voltage Ref2 may be transmitted to a positive (+) input terminal of the first comparator 132b, and the first reference voltage Ref1 may be transmitted to a negative (−) input terminal of the first comparator 132b. And, when the size of the first reference voltage Ref1 is smaller than the size of the second reference voltage Ref2, a high signal may be output. Also, the first comparator 132b may increase a frequency of a signal output from the oscillator 132a when the size of the first reference voltage Ref1 is equal to or smaller than the size of the second reference voltage Ref2. Here, the first comparator 132b may correspond to the monitoring unit 130a shown in FIG. 1.

The second signal generation unit 133 may include a second comparator 133a, and the second comparator 133a may compare the first reference voltage Ref1 and the sensing voltage VS. The second comparator 133a may receive the sensing voltage VS through a positive (+) input terminal and receive the first reference voltage Ref1 through a negative (−) input terminal. And, when the size of the sensing voltage VS reaches the first reference voltage Ref1, the second comparator 133a may transmit the second signal R of a high state to the switch signal unit 131. The second signal generation unit 133 may adjust a transmission time of the second signal by the variable first reference voltage Ref1. The amount of the current flowing through the inductor L may be adjusted since the turn-off time of the switch SW1 is long when the transmission time of the second signal R is early and the turn-off time of the switch SW1 is short when the transmission time of the second signal R is late.

Further, the control unit 130 may further connect a timer 134 to an output terminal of the switch signal unit 131. The timer 134 may delay the control signal CS, which is output from the output terminal of the switch signal unit 131, by a predetermined time. When the switch SW1 is turned on, the size of the driving current ID flowing through the inductor L may be increased such that the sensing voltage VS sensed by the sensing unit 120 may be increased. At this time, although the sensing voltage VS reaches the first reference voltage Ref1, since the switch SW1 is turned off after the time delayed by the timer 134, average current control for uniformly maintaining the average of the driving current ID flowing through the inductor L can be performed by adjusting a time for delaying the operation of the switch SW1 by the control signal CS.

FIG. 5 is a waveform diagram showing the waveform of the current flowing through the inductor of the power converter shown in FIG. 1.

FIG. 5 shows the waveform of the driving current ID when the average of the driving current ID flowing through the inductor L is set to 50 mA. When the frequency of the first signal S is increased by the control unit 130, while a turn-on period of the switch SW1 is increased, a turn-off period of the switch SW1 is reduced. Thus, a period in which the driving current ID flowing through the inductor L is reduced is shortened such that the minimum value of the driving current ID flowing through the inductor L is increased. Thus, although the first reference voltage Ref1 is varied and thus the voltage level of the first reference voltage Ref1 becomes lower than the voltage level of the second reference voltage Ref2, since the size of the driving current ID does not have a value of 0 or a value approximate to 0 unlike FIG. 2, the control of the power converter 100 can be smoothly performed.

The controller and the power converter using the same according to the present invention can prevent malfunction of the power converter during dimming control for adjusting brightness. Further, the controller and the power converter using the same according to the present invention can connect loads having different power consumption by expanding the voltage range of power supplied from the power converter.

The functions of the various elements shown in the drawings may be provided through the use of dedicated hardware as well as hardware capable of executing software in association with appropriate software. When provided by a processor, the functions may be provided by a single dedicated processor, by a single shared processor, or by a plurality of individual processors, some of which may be shared.

In the claims hereof, any element expressed as a means for performing a specified function is intended to encompass any way of performing that function including, for example, a combination of circuit elements which performs that function or software in any form, including, therefore, firmware, microcode or the like, combined with appropriate circuitry for executing that software to perform the function.

Reference in the specification to “an embodiment” of the present principles, as well as other variations thereof, means that a particular feature, structure, characteristic, and so forth described in connection with the embodiment is included in at least one embodiment of the present principles. Thus, the appearances of the phrase “in an embodiment”, as well as any other variations, appearing in various places throughout the specification are not necessarily all referring to the same embodiment.

Reference in the specification to “connect” or “connecting”, as well as other variations thereof, means that an element is directly connected to the other element or indirectly connected to the other element through another element. Throughout this specification, the singular form includes the plural form unless the context clearly indicates otherwise. When terms “comprises” and/or “comprising” used herein do not preclude existence and addition of another component, step, operation and/or device, in addition to the above-mentioned component, step, operation and/or device.

1. A controller comprising:
a switch signal unit configured to output a control signal repeating a high state and a low state, by receiving a first signal and a second signal;
a first signal generation unit configured to generate the first signal, and configured to transmit the first signal to the switch signal unit; and
a second signal generation unit configured to generate the second signal by comparing a sensing voltage and a variable first reference voltage, and configured to transmit the second signal to the switch signal unit, wherein the first signal generation unit is configured to adjust a transmission time of the first signal by sensing a voltage level of the first reference voltage.

2. The controller according to claim 1, wherein the first signal generation unit comprises an oscillator, wherein the oscillator is configured to adjust the transmission time of the first signal in response to the voltage level of the first reference voltage.

3. The controller according to claim 1, wherein the first signal generation unit further comprises a first comparator, wherein the first comparator is configured to adjust the transmission time of the first signal, by comparing the first reference voltage and a second reference voltage.

4. The controller according to claim 1, wherein the second signal generation unit comprises a second comparator, wherein the second comparator is configured to compare the first reference voltage and the sensing voltage.

5. The controller according to claim 1, wherein a timer for delaying the control signal by a predetermined time is further connected to an output terminal of the switch signal unit.

6. A power converter comprising:
an inductor;
a switch configured to be turned on or turned off according to a control signal, to control the flow of a current flowing through the inductor; and
a control unit configured to output the control signal, wherein the control unit comprises:
a switch signal unit configured to output the control signal repeating a high state and a low state, by receiving a first signal and a second signal;
a first signal generation unit configured to generate the first signal, and configured to transmit the first signal to the switch signal unit; and
a second signal generation unit configured to generate the second signal by comparing a sensing voltage and a variable first reference voltage, and configured to transmit the second signal to the switch signal unit, wherein the first signal generation unit is configured to adjust a transmission time of the first signal by sensing a voltage level of the first reference voltage.

7. The power converter according to claim 6, wherein the first signal generation unit comprises an oscillator, wherein the oscillator is configured to adjust the transmission time of the first signal in response to the voltage level of the first reference voltage.

8. The power converter according to claim 7, wherein the first signal generation unit further comprises a first comparator, wherein the first comparator is configured to adjust the transmission time of the first signal, by comparing the first reference voltage and a second reference voltage.

9. The power converter according to claim 6, wherein the second signal generation unit comprises a second comparator, wherein the second comparator is configured to compare the first reference voltage and the sensing voltage.

10. The power converter according to claim 9, wherein a voltage level of the sensing voltage is varied in response to the size of the current flowing through the inductor.

11. The power converter according to claim 6, wherein a timer for delaying the control signal by a predetermined time is further connected to an output terminal of the switch signal unit.

12. A power converter comprising:
a power generation unit configured to apply a predetermined voltage to a load, and to flow a driving current through an inductor;
a sensing unit configured to sense the size of the driving current, and to output a sensing voltage corresponding to the size of the driving current; and
a control unit configured to output a control signal to make uniform an average of the size of the driving current, in response to the size of a first reference voltage, while adjusting the average of the size of the driving current by varying a voltage level of the first reference voltage.

13. The power converter according to claim 12, wherein the control unit further comprises a monitoring unit configured to sense the voltage level of the first reference voltage, and to prevent the amount of the current flowing through the inductor from being reduced to less than a predetermined value, when the size of the first reference voltage sensed by the monitoring unit is below a predetermined level.

14. The power converter according to claim 13, wherein the power generation unit comprises a switch connected to the inductor, and is configured to adjust a flow of the driving current flowing through the inductor, by performing a switching operation according to the control signal.

15. The power converter according to claim 14, wherein the control unit comprises an oscillator for configured to transmit the control signal for turning on the switch, a second comparator for configured to transmit the control signal for turning off the switch, and a switch signal unit configured to selectively output the control signal by receiving output signals of the oscillator and the second comparator.

16. The power converter according to claim 15, wherein the control unit further comprises a timer, wherein the timer is configured to delay the output signal of the switch signal unit.

17. The power converter according to claim 15, wherein the monitoring unit is configured to increase a frequency of the signal output from the oscillator, when the size of the first reference voltage is less than a predetermined value.

18. The power converter according to claim 17, wherein the monitoring unit comprises a second comparator, and wherein the second comparator is configured to compare the first reference voltage and a second reference voltage.
